(19) United States
(12) Patent Application Publication
(10) Pub. No.: US 2013/0062721 A1
(43) Pub. Date: Mar. 14, 2013

(54) SEMICONDUCTOR STRIP DETECTOR

(71) Applicants: Kazuyuki MATSUSHITA, Tokyo (JP); Masaru KURIBAYASHI, Tokyo (JP)

(72) Inventors: Kazuyuki MATSUSHITA, Tokyo (JP); Masaru KURIBAYASHI, Tokyo (JP)

(73) Assignee: RIGAKU CORPORATION, Tokyo (JP)

(21) Appl. No.: 13/572,931

(22) Filed: Aug. 13, 2012

(30) Foreign Application Priority Data
Sep. 8, 2011 (JP) 2011-196275

(51) Int. Cl. H01L 27/14

(52) U.S. Cl. 257/448; 257/E27.122

(57) ABSTRACT

The present invention provides a semiconductor strip detector that can reduce noise generated from floating capacitance between electrodes while maintaining high detection efficiency. The semiconductor strip detector for detecting radiation includes: a substrate integrally formed from semiconductor and receiving incident radiation; a first electrode group made up of a plurality of strip-shaped electrodes to provided in parallel to each other on a major surface of the substrate; and a second electrode group made up of a plurality of strip-shaped electrodes to provided coaxially with an orthogonal projection of the plurality of strip-shaped electrodes to of the first electrode group onto the major surface of the substrate, and the electrode groups are formed so that a ratio of a longitudinal length to an electrode-to-electrode length is 10 or more. Therefore, noise can be sufficiently reduced while a detection range is being maintained.

### BACKGROUND OF THE INVENTION

1. Field of the Invention

The present invention relates to a semiconductor strip detector that detects radiation.

2. Description of Related Art

A silicon strip detector (SSD) is a solid-state detector configured to form a strip-shaped slender p-type semiconductor layer on an n-type semiconductor wafer surface and to mount an aluminum electrode on the semiconductor layer, and is capable of detecting incident charged particles or radiation. In recent years, the silicon strip detector has been used, particularly for high-speed measurement or one-dimensional measurement in an X-ray diffraction field.

Such a silicon strip detector generates leak currents at a strip-shaped electrode due to surrounding heat to thereby cause noise. In addition, the floating capacitance between electrodes generates leak currents to cause noise in the same way. The generated noise degrades the energy resolution of a detected value. The following matters are known as background art that requires measures against noise from such a detector.

The most common technique is a technique for cooling a silicon strip detection element by using peltiert element, liquid nitrogen or the like. However, the technique has demerits such as dew condensation caused by cooling and cost increase. In contrast to this, the semiconductor detector disclosed in Japanese Unexamined Patent Application Publication No. 10-335691 reduces two fluctuations ΔEd and ΔEp which determine the energy resolution of the semiconductor detector by forming a semiconductor element from black phosphorous material, to thereby improve the energy resolution. The semiconductor radiation detector disclosed in Japanese Unexamined Patent Application Publication No. 2000-356680 includes a threshold amplifier which has a threshold value provided for a peak value of an input signal in order to remove electronic noise caused by leak currents from the detector.

The semiconductor sensor disclosed in Japanese Unexamined Patent Application Publication No. 2008-209294 reduces the generation of vibrating noise by maintaining a conductive layer at the same potential as that of a shield case even when the semiconductor sensor vibrates through the connection of the conductive layer and the shield case, therefore reducing floating capacitance between the conductive layer and the shield case as well as reducing inputs and outputs of charges into/from respective positive and negative electrodes caused by vibration. The ionization chamber detector disclosed in Japanese Unexamined Patent Application Publication No. 2010-156671 subtracts noise generated on a dummy signal line from signals output from the signal lines and compensates for noise superimposed on the signal lines, by a plurality of dummy signal lines being arranged in the vicinity of the plurality of signal lines connected to respective divided electrodes.

However, even if conventional measures against noise as described above are applied to a strip detector, the noise resulting from floating capacitance between strip-shaped electrodes cannot be significantly reduced. In contrast to this, because the magnitude of a leak current has a correlation with the magnitude of the capacitance between the electrodes, a method for shortening the strip-shaped electrodes is conceivable, but the shortening of the electrodes reduces an X-ray detection area to thereby degrade detection efficiency.

### BRIEF SUMMARY OF THE INVENTION

The present invention has been made in view of the above-mentioned circumstances and an object of the present invention is to provide a semiconductor strip detector capable of reducing noise resulting from floating capacitance between electrodes while maintaining high detection efficiency.

(1) In order to achieve the above-mentioned object, the semiconductor strip detector according to the present invention is a semiconductor strip detector for detecting radiation, and includes: a substrate integrally formed from semiconductor and receiving incident radiation; a first electrode group made up of a plurality of strip-shaped electrodes provided in parallel to each other on a major surface of the substrate; and a second electrode group made up a plurality of strip-shaped electrodes provided coaxially with an orthogonal projection of the plurality of strip-shaped electrodes of the first electrode group onto the major surface of the substrate, in which the first and the second electrode groups are both configured to be formed so that a ratio of a longitudinal length to an electrode-to-electrode length is 10 or more.

As described above, the semiconductor strip detector according to the present invention includes the plurality of electrode groups provided coaxially with an orthogonal projection of the plurality of strip-shaped electrodes. Therefore, by the reduction of the electrode length per electrode group and the reduction of floating capacitance between the electrodes while maintaining a detection range, the resulting noise can be sufficiently reduced. As a consequence, energy resolution can be enhanced.

(2) The semiconductor strip detector according to the present invention is configured so that the first and the second electrode groups are both provided on the same major surface of the substrate. Therefore, according to a semiconductor manufacturing process, the plurality of electrode groups on which the respective strip-shaped electrodes are provided integrally on the substrate and coaxially can be easily formed, and manufacturing cost can be reduced. Additionally, a gap between the electrode groups can be significantly reduced.

(3) The semiconductor strip detector according to the present invention is configured so that the first and the second electrode groups are both provided adjacent to each other, having a gap of 1 mm or less therebetween. Accordingly, for example, compared with a plurality of detectors each of which has only one electrode group and is connected to another, a dead region between the electrode groups can be significantly reduced, and an adverse effect of the dead region can be reduced.

(4) The semiconductor strip detector according to the present invention is configured so that the first electrode group is provided on a different major surface from that provided with the second electrode group. Therefore, a gap between the electrode groups provided on different major surfaces in an orthogonal projection onto the major surfaces can be set to zero.

(5) Furthermore, the semiconductor strip detector according to the present invention is configured so that three or more electrode groups having a relationship between the first electrode group and the second electrode group one another are provided. Therefore, an electrode length per electrode group can be further reduced for the same detection range and noise can be further reduced.

According to the present invention, noise resulting from floating capacitance between the electrodes can be reduced while high detection efficiency being maintained. As a consequence, energy resolution of a detected value can be enhanced.

### BRIEF DESCRIPTION OF THE SEVERAL VIEWS OF THE DRAWINGS

FIG. 1 is a perspective view showing a semiconductor strip detector and a readout circuit according to the embodiment 1;

FIG. 2 is a cross-sectional view showing a semiconductor strip detector according to the embodiment 1;

FIG. 3 is a cross-sectional view showing a semiconductor strip detector according to the embodiment 1;

FIG. 4 is a cross-sectional view showing a semiconductor strip detector according to the embodiment 1;

FIG. 5 is a block diagram showing a circuit for processing a detected signal;

FIG. 6 is a cross-sectional view showing a semiconductor strip detector according to the embodiment 2;

FIG. 7 is a cross-sectional view showing a semiconductor strip detector according to the embodiment 2; and

FIG. 8 is a cross-sectional view showing a semiconductor strip detector according to embodiment 2.

### DETAILED DESCRIPTION OF THE INVENTION

Next, the embodiment of the present invention will be described with reference to the accompanying drawings. For easy understanding of description, the same reference numbers and designations in respective drawings refer to the same elements, and duplicated description is omitted.

### First Embodiment

### (Detector and Readout Circuit)

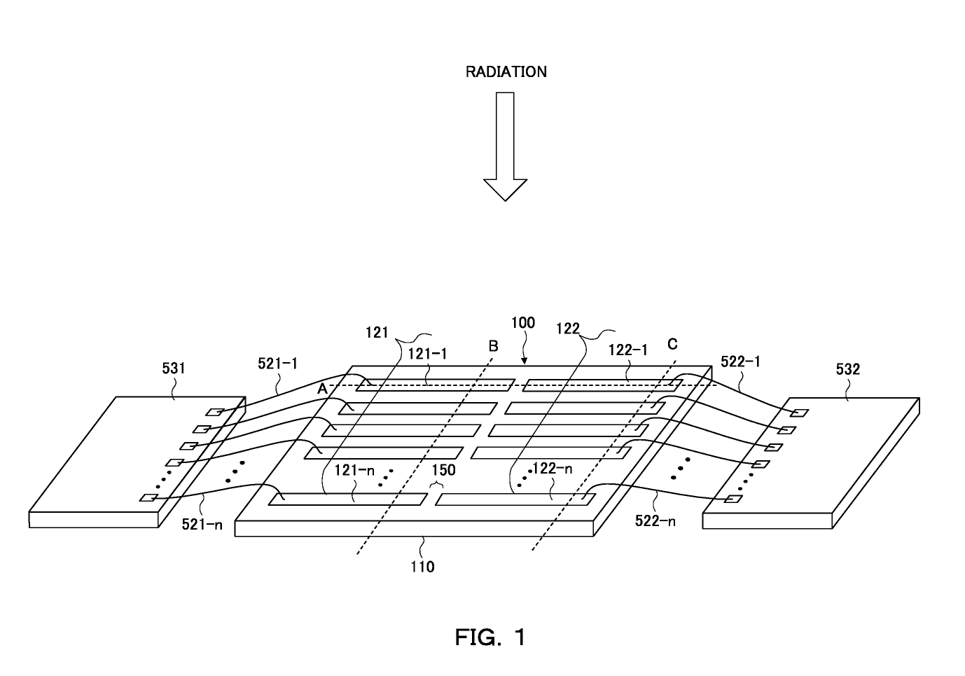

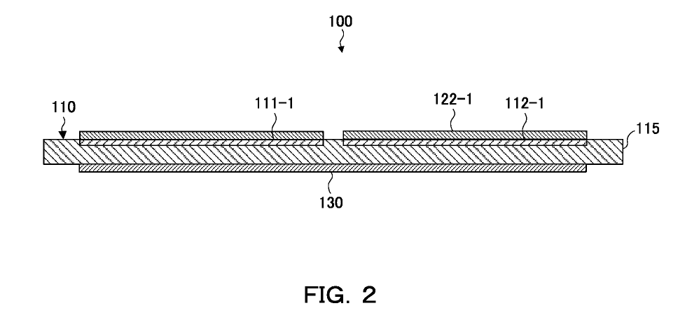

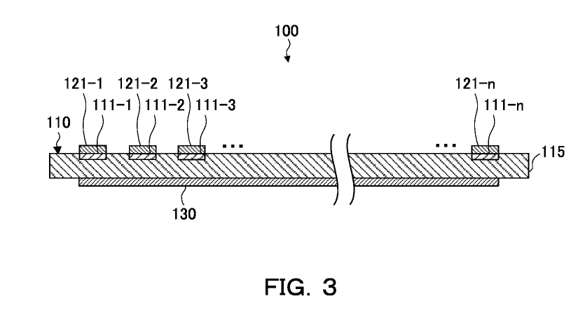

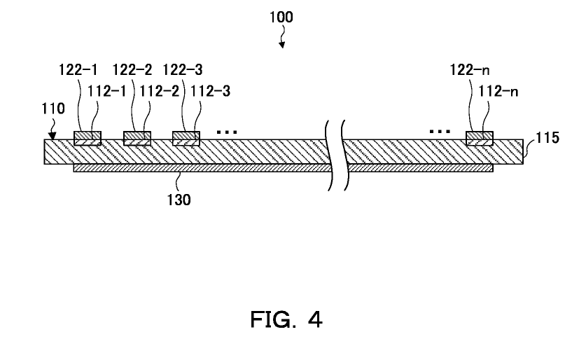

FIG. 1 is a perspective view showing a semiconductor strip detector 100 and readout circuits 531 and 532. Furthermore, FIGS. 2 to 4 are cross-sectional views showing a semiconductor strip detector 100. FIG. 2 is a cross-sectional view taken on line A of FIG. 1. FIG. 3 is a cross-sectional view taken on line B of FIG. 1. FIG. 4 is a cross-sectional view taken on line C of FIG. 1.

The semiconductor strip detector 100 is a semiconductor detector having a p-n junction surface formed into a strip shape and detecting radiation. Preferably, a semiconductor material to be used is a silicon semiconductor, but other materials may be used. The radiation to be detected is preferably X-rays or g-rays, and the semiconductor strip detector 100 is effective, particularly in detecting the position and intensity of a diffracted line in an X-ray diffraction field. The semiconductor detector creates electron-hole pairs along a path while radiation passes through a depleted layer enlarged by applying reverse bias. The semiconductor detector separates the created electrons and holes, and reads out charge quantity thereof with an electrode, thereby being able to detect radiation.

As shown in FIGS. 1 to 4, the semiconductor strip detector 100 includes a substrate 110, an electrode group 121 (a first electrode group), an electrode group 122 (a second electrode group), and an electrode 130. The substrate 110 is integrally formed from a semiconductor material and electric charges are moved by the incidence of radiation. The substrate 110 has a bulk body 115 and strip bodies 111-1 to 111-n and 112-1 to 112-n. The bulk body 115 is formed from, for example, n-type semiconductor, and the strip bodies 111-1 to 111-n and 112-1 to 112-n are formed from p-type semiconductors. In this case, a p-n junction surface is formed therebetween.

The electrode group 121 is comprised of the plurality of strip-shaped electrodes 121-1 to 121-n provided in parallel to each other on a major surface of the substrate 110. Meanwhile, the major surface refers to the widest surface of a plate-like body. In addition, similarly, the electrode group 122 is comprised of the plurality of strip-shaped electrodes 122-1 to 122-n provided in parallel to each other on the major surface of the substrate 110. The strip-shaped electrodes 122-1 to 122-n are provided coaxially with an orthogonal projection of the plurality of strip-shaped 121-1 to 121-n of the first electrode group 121 onto the major surface of the substrate 110.

The strip-shaped electrode 121-1 and the strip-shaped electrode 122-1 are provided coaxially with each other on the major surface of the substrate 110. The same applies to the relationship between the strip-shaped electrode 121-2 and the strip-shaped electrode 122-2. In other words, the semiconductor strip detector 100 has such a structure that the strip-shaped electrodes provided in parallel to each other are divided. Therefore, an electrode length per electrode group can be reduced while a detection area is being maintained. By the reduction of a floating capacitance between the strip-shaped electrodes, the resulting noise can be sufficiently reduced. Meanwhile, each of the strip-shaped electrodes is formed so as to be superimposed on the corresponding strip body and is designed to have the same dimensions such as width, pitch and longitudinal length.

The length of each of the strip-shaped electrodes in the electrode group is the same, and the length of the electrode group in the longitudinal direction of the strip-shaped electrodes means that of each of the strip-shaped electrodes. In addition, an electrode-to-electrode length (pitch) is also the same in the electrode group. The semiconductor strip detector 100 is shaped preferably such that a strip having a length capable of covering a range desired to be detected is divided into two in the center. For example, in the case where a dimension of 20 mm is required as a detection range, two electrode groups can be provided with a length of each of the strip-shaped electrodes defined at 10 mm. Additionally, the electrode groups 121, 122 are formed so that a ratio (a pitch ratio) of a longitudinal length to an electrode-to-electrode length is 10 or more. Therefore, that is not to mean that the electrode group has such an electrode structure as a finely divided pixel detector. The electrode width will be described later.

As shown in FIGS. 1 to 4, it is preferable that the electrode groups 121, 122 are both provided on the same major surface of the substrate 110. Therefore, according to a semiconductor manufacturing process, the respective strip-shaped electrodes can be easily integrally formed on the substrate 110, and thus manufacturing cost can be reduced. Moreover, a gap between the electrode groups can be sufficiently reduced.

The electrode groups 121 and 122 are provided to be adjacent to each other, having a gap 150 of 1 mm or less therebetween. Accordingly, for example, even if a detector is manufactured by connecting a plurality of common detectors each of which is provided with only one electrode group, a dead region between the electrode groups cannot be sufficiently reduced, and thus an adverse effect of the dead region is unavoidable.

A plurality of readout circuits 531 and 532 is provided for each electrode group and reads out signals from the electrode groups. The plurality of readout circuits is required, but can be composed of integrated circuit, and thus no significant burden is placed on the configuration of the detector. In an embodiment shown in FIG. 1, the readout circuit 531 is connected with each of the strip-shaped electrodes 121-1 to 121-n of the first electrode group 121 through wire bonding 521-1 to 521-n.

In addition, the readout circuit 532 is connected with each of the strip-shaped electrodes 122-1 to 122-n of the second electrode group 122 through wire bonding 522-1 to 522-n. When radiation enters into the substrate 110, charge flows into the strip-shaped electrode nearest to the position, and thus the readout circuit 531 can detect the position and intensity.

Such a semiconductor strip detector 100 can be manufactured by using a common semiconductor manufacturing process, based on the design determined to provide the plurality of electrode groups as described above.

### (Processing Circuit for Signals)

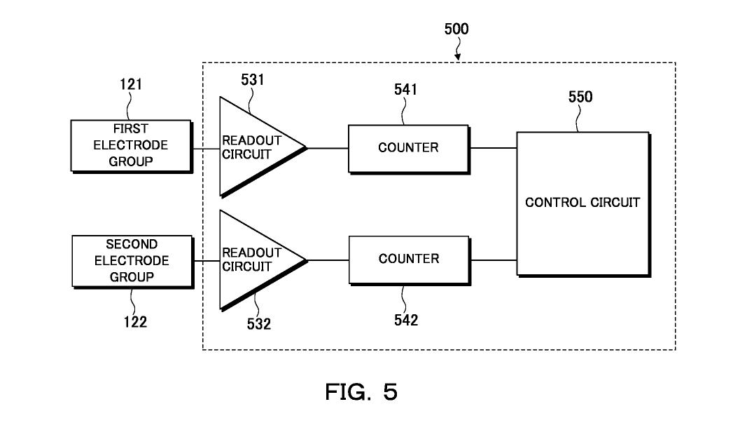

Next, a processing circuit for signals detected by the semiconductor strip detector 100 will be described below. FIG. 5 is a block diagram showing a processing circuit 500 for processing detected signals. As shown in FIG. 5, the processing circuit 500 has the readout circuits 531 and 532, counters 541 and 542, and a control circuit 550.

Each of the readout circuits 531, 532 reads out signals from the first electrode group 121 and the second electrode group 122. The read-out signals are input into the counters 541 and 542, and the counters 541 and 542 count the number of times of input pulse signals. The control circuit 550 adds, onto the counted number of times, the number of times counted at the coaxially positioned strip-shaped electrode between different electrode groups. Detection and counting are performed through the divided electrode groups and subsequently the addition of the number of counts enables significantly reducing noise. Therefore, a detector with high energy resolution can be realized without sacrifice of a detection area. Meanwhile, addition of the number of counts may be made in the control circuit 550 or on software.

### (Verification of Influence of Electrode Width)

In the above-mentioned example, the electrode width of the strip-shaped electrode is not particularly determined, and the reason why the determination of the electrode width is unnecessary will be described in the following. Two sets of semiconductor strip detector provided with two electrode groups on the same major surface were prepared, each designed to have a strip-shaped electrode length, pitch, and electrode width shown in the table below. Any of the semiconductor strip detectors was designed to have the same electrode length and pitch with an electrode width or a gap between electrodes changed. For each of the electrode groups of the semiconductor strip detector, the electrostatic capacity between the electrodes was measured. Measurement of the electrostatic capacity was performed by using a method in conformity with JIS C 5101-1.

TABLE 1

| ELEC- | | | ELEC- | | ELECTRO- |
|---|---|---|---|---|---|
| TRODE | | | TRODE | | STATIC |
| LENGTH/ | PITCH/ | PITCH | WIDTH/ | GAP/ | CAPAC- |
| mm | μm | RATIO | μm | μm | ITY/pF |
| 10 | 100 | 100 | 26 | 75 | 2.62 |
| 10 | 100 | 100 | 15 | 85 | 2.14 |

Consequently, as shown in Table 1, while the electrostatic capacity in the case of a electrode width of 26 μm was 2.62 pF, it was 2.14 pF in the case of a electrode width of 15 μm which is approximately half the former value, and thus a difference in the electrostatic capacity was approximately 20%, which indicates that the effect is low. Accordingly, the difference between the electrodes does not dramatically make a contribution to the electrostatic capacity between the electrodes, and thus another method is required.

### Second Embodiment

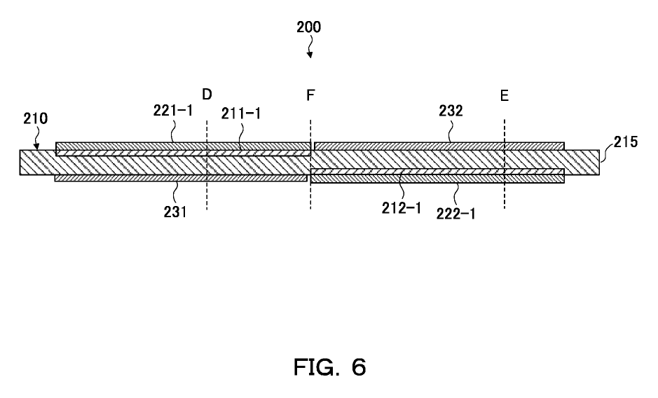

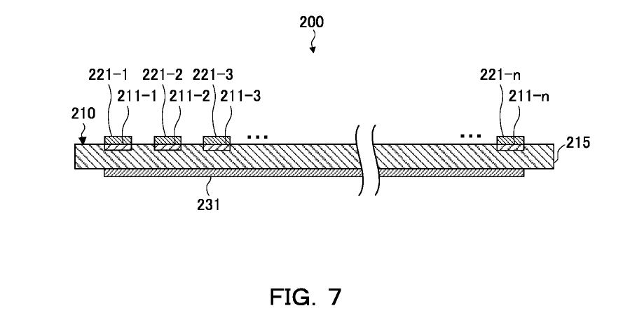

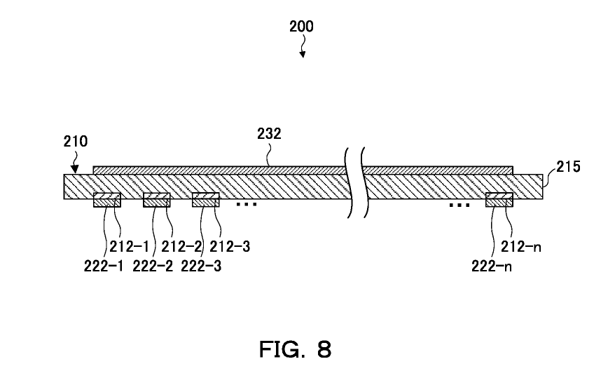

The above-mentioned embodiment describes that the electrode group 121 and the electrode group 122 are provided on the same major surface, but a major surface on which each of the electrode groups is provided may be different from each other. FIGS. 6 to 8 are a cross-sectional view showing a semiconductor strip detector 200. FIG. 6 is a cross-sectional view taken along the axis of the strip-shaped electrode, FIG. 7 is a cross-sectional view taken on line D of FIG. 6, and FIG. 8 is a cross-sectional view taken on line E of FIG. 6.

As shown in FIGS. 6 to 8, the semiconductor strip detector 200 includes a substrate 210, a first electrode group 221, a second electrode group 222, and electrodes 231 and 232. The substrate 210 has a bulk body 215 and strip bodies 211-1 to 211-n and 212-1 to 212-n. The first electrode group 221 is made up of strip-shaped electrodes 221-1 to 221-n. Furthermore, the first electrode group 222 is made up of strip-shaped electrodes 222-1 to 222-n.

In the semiconductor strip detector 200, the electrode group 221 (a first electrode group) is provided on a major surface different from a major surface on which the electrode group 222 (a second electrode group) is provided. Therefore, between the electrode groups 221 and 222 provided on the different major surfaces, a gap between the electrode groups adjacent to each other (corresponding to a gap 150 shown in FIG. 1, for example), generated in an orthogonal projection onto the major surface can be set to zero. Meanwhile, a direction F shown in FIG. 6 indicates a normal direction to the major surface of the substrate 210, and it can be seen that the semiconductor strip detector 200 can be designed to set the gap to zero. The semiconductor strip detector 200 can be formed by the application of a multilayer technology of semiconductor manufacturing process.

### Other Embodiments

In the above-mentioned embodiment, the semiconductor strip detector has two electrode groups, but three or more electrode groups having a relationship between the first electrode group and the second electrode group may be provided. Therefore, an electrode length per electrode group can be reduced for the same detection range, and furthermore, noise can be reduced.

1. A semiconductor strip detector for detecting radiation, comprising:
a substrate integrally formed from semiconductor and receiving incident radiation;
a first electrode group including a plurality of strip-shaped electrodes provided in parallel to each other on a major surface of the substrate; and
a second electrode group including a plurality of strip-shaped electrodes provided coaxially with an orthogonal projection of the plurality of strip-shaped electrodes of the first electrode group onto the major surface of the substrate, wherein
the first and the second electrode groups are both formed so that a ratio of a longitudinal length to an electrode-to-electrode length is 10 or more.

2. The semiconductor strip detector according to claim 1, wherein the first and the second electrode groups are both provided on the same major surface of the substrate.

3. The semiconductor strip detector according to claim 2, wherein the first and the second electrode groups are provided adjacent to each other, having a gap of 1 mm or less therebetween.

4. The semiconductor strip detector according to claim 1, wherein the first electrode group is provided on a different major surface from that provided with the second electrode group.

5. The semiconductor strip detector according to claim 1, wherein three or more electrode groups having a relationship between the first electrode group and the second electrode group are provided.
